(19) United States
(12) Patent Application Publication
(10) Pub. No.: US 2020/0381897 A1
(43) Pub. Date: Dec. 3, 2020

(54) VERTICAL-CAVITY SURFACE-EMITTING LASER WITH CHARACTERISTIC WAVELENGTH OF 910 NM

(71) Applicant: Mellanox Technologies, Ltd., Yokneam (IL)

(72) Inventors: Isabelle Cestier, Haifa (IL); Itshak Kalifa, Bat Yam (IL); Elad Mentovich, Tel Aviv (IL); Matan Galanty, Kurzim (IL)

(21) Appl. No.: 16/890,149

(22) Filed: Jun. 2, 2020

Related U.S. Application Data
(60) Provisional application No. 62/856,322, filed on Jun. 3, 2019.

(51) Int. Cl. H01S 5/183; H01S 5/343

(52) U.S. Cl. CPC H01S 5/18347; H01S 5/34353; H01S 5/34313; H01S 5/18366

(57) ABSTRACT

A vertical-cavity surface-emitting laser (VCSEL) and method of fabrication thereof is provided. The VCSEL includes a mesa structure disposed on a substrate. The mesa structure has a first reflector stack, a second reflector stack, and an active region disposed between the first and second reflector stacks. The active region is configured to cause the VCSEL to emit light having a characteristic wavelength of 910 nanometers. The active region includes alternating layers of quantum wells and barriers, the quantum wells having high indium content (up to 18%). The VCSEL features a first contact layer disposed at least partially on a surface of the mesa structure and configured to serve as an electrical signal layer and a second contact layer disposed at least partially about the mesa structure and configured to serve as an electrical ground.

### RELATED APPLICATION INFORMATION

The following application claims priority from U.S. Provisional Application No. 62/856,322, filed Jun. 3, 2019, the content of which is incorporated herein by reference in its entirety.

### BACKGROUND

As data communication demands increase in both volume and speed, fiber optics have become an increasingly popular communication approach. One emerging element of this approach for generating the data stream communicated through fiber optics cables comprises a VCSEL optically coupled with a single mode fiber. However, emitting a single channel along fiber optics cable is insufficient to meet current and growing optical communication demands. Techniques for multiplexing multiple channels into one multi-mode fiber have been developed, such as wavelength division multiplexing (WDM). These techniques require sufficient spread between the wavelengths of the signals being multiplexed together to allow for appropriate demultiplexing by the receiver.

### BRIEF SUMMARY

The use of VCSELs for transmission of optical signals in fiber optic systems has provided several advantages over edge-emitting lasers. For example, VCSELs generally require less power consumption and can be manufactured more efficiently than edge-emitting lasers, especially when on-chip testing capability is provided, which can result in a considerable cost advantage as compared to edge-emitting lasers. Furthermore, VCSELs typically provide reliable operation over time, which can be very important for applications in fiber optic systems. Multiplexing of optical signals may be performed for increasing the number of channels available via an optical fiber. Generally, the multiplexing is performed using VCSELs having characteristic or nominal wavelengths (referred to as characteristic wavelengths herein) of 850 nm, 1100 nm, and 1310 nm. However, use of VCSELs having characteristic wavelengths outside of these three traditional wavelength regimes may assist in increasing the number of channels and/or the bandwidth available via a single optical fiber.

Various embodiments provide VCSELs having a characteristic wavelength of 910 nm. In various embodiments, the VCSELs comprise active regions comprising a plurality of quantum wells. In various embodiments, the quantum wells are formed using InGaAs wells separated by AlGaAs barriers. In various embodiments, the InGaAs wells may have a high level of Indium up to 18% (e.g., the wells may be characterized by InₓGa₍₁₋ₓ₎As, where x is in the range of 0.1 to 0.2). In various embodiments, the AlGaAs barriers may have low levels of Aluminum (e.g., the barriers may be characterized by Al_{y}Ga_{(1-y)}As, where y is in the range of 0.05 to 0.35).

According to a first aspect of the present disclosure, a vertical-cavity surface-emitting laser (VCSEL) of the present invention comprises a mesa structure disposed on a substrate comprising a first reflector stack, a second reflector stack, and an active region disposed between the first and second reflector stacks. In various embodiments, the active region is configured to cause the VCSEL to emit light having a characteristic wavelength of 910 nanometers. In an example embodiment, the VCSEL further comprises a first contact layer disposed at least partially on a surface of the mesa structure opposite the substrate. The first contact layer is configured to serve as an electrical signal layer. In an example embodiment, the VCSEL further comprises and a second contact layer disposed at least partially about the mesa structure and configured to serve as an electrical ground. In an example embodiment, the first and second contact layers may be in a ground-signal-ground (GSG) layout with an etched shape around the VCSEL mesa, such that the data transmission capabilities of the VCSEL are not limited by the parasitic capacitance of traditional VCSEL layout designs.

In an example embodiment, the active region of the VCSEL is comprised of a plurality of quantum wells each comprising up to 18% indium and a plurality of barriers each comprising 5 to 37% aluminum. In an example embodiment, the active region comprises a plurality of alternating layers of quantum wells and barriers. Each quantum well layer may comprise an indium gallium arsenide alloy, and each barrier layer may comprise an aluminum gallium arsenide alloy. In an example embodiment, the thickness and aluminum content of each barrier layer is configured to cause the VCSEL to emit light having a characteristic wavelength of 910 nanometers. In an example embodiment, the first and second reflector stacks each comprise a plurality of reflector layers. The thickness of each reflector layer may be configured to cause the VCSEL to emit light having a characteristic wavelength of 910 nanometers. In an example embodiment, the first and second reflector stacks each further comprise a buffer layer bordering the active region. Each buffer layer of the first and second reflector stacks may have a thickness greater than the thickness of the remaining reflector layers of the plurality of reflector layers. In an example embodiment, the first contact layer extends in at least a partially circular shape around an emission window of the VCSEL and has a first diameter and the second contact layer extends in an arc around the mesa structure and has a second diameter greater than the first diameter. In an example embodiment, the second diameter is two or four times greater than the first. In an example embodiment, a cavity resonance of a VCSEL cavity formed by the first and second reflector stacks and a photoluminescence peak of the active region are detuned to below the characteristic wavelength of 910 nanometers in an instance in which the first contact layer is not conducting an electrical current and the VCSEL has a temperature below 23 degrees Celsius. In an example embodiment, the cavity resonance and the photoluminescence peak of the active region are configured to shift towards 910 nanometers in an instance in which the first contact layer conducts electrical current and the VCSEL increases in temperature above 23 degrees Celsius.

According to another aspect of the present invention, a method for manufacturing or fabrication a vertical-cavity surface-emitting laser (VCSEL) is provided. In an example embodiment, the method comprises dry etching a VCSEL blank to define a mesa structure disposed on a substrate; wet etching the mesa structure to define a first reflector stack, a second reflector stack, and an active region disposed between the first and second reflector stacks. The active region is configured to cause the VCSEL to emit light having a characteristic wavelength of 910 nanometers. The method further comprises depositing a first contact layer at least partially on a surface of the mesa structure opposite the substrate. The first contact layer is configured to serve as an electrical signal layer. The method further comprises depositing a second contact layer at least partially about the mesa structure. The second contact layer is configured to serve as an electrical ground.

In an example embodiment, the active region of the VCSEL comprises a plurality of quantum wells each comprising up to 18% indium and a plurality of barriers each comprising 5 to 37% aluminum. In an example embodiment, the active region comprises a plurality of alternating layers of quantum wells and barriers. Each quantum well layer may comprise an indium gallium arsenide alloy, and each barrier layer may comprise an aluminum gallium arsenide alloy. In an example embodiment, the thickness and aluminum content of each barrier layer is configured to cause the VCSEL to emit light having a characteristic wavelength of 910 nanometers. In an example embodiment, the first and second reflector stacks each comprise a plurality of reflector layers. The thickness of each reflector layer may be configured to cause the VCSEL to emit light having a characteristic wavelength of 910 nanometers. In an example embodiment, the first and second reflector stacks each further comprise a buffer layer bordering the active region. Each buffer layer of the first and second reflector stacks may have a thickness greater than the thickness of the remaining reflector layers of the plurality of reflector layers. In an example embodiment, the first contact layer extends in an at least partially circular shape around an emission window of the VCSEL and has a first diameter and the second contact layer extends in an arc around the mesa structure and has a second diameter greater than the first diameter. In an example embodiment, the second diameter is two to four times greater than the first diameter. In an example embodiment, a cavity resonance of a VCSEL cavity formed by the first and second reflector stacks and a photoluminescence peak of the active region are detuned to below the characteristic wavelength of 910 nanometers in an instance in which the first contact layer is not conducting an electrical current and the VCSEL has a temperature below 23 degrees Celsius. In an example embodiment, the cavity resonance and the photoluminescence peak of the active region are configured to shift towards 910 nanometers in an instance in which the first contact layer conducts electrical current and the VCSEL increases in temperature above 23 degrees Celsius.

### BRIEF DESCRIPTION OF THE DRAWING(S)

Having thus described the invention in general terms, reference will now be made to the accompanying drawings, which are not necessarily drawn to scale, and wherein:

FIG. 1 illustrates a schematic top view of a typical ground-signal-ground vertical-cavity surface-emitting laser (VCSEL) layout;

FIG. 2 illustrates a schematic side view of a VCSEL having a characteristic wavelength of 910 nm according to an example embodiment;

FIG. 3 illustrates a perspective top view of a ground-signal-ground VCSEL layout with a VCSEL having a characteristic wavelength of 910 nm according to an example embodiment;

FIG. 4 illustrates a partial cross-section view of a VCSEL configured to emit light having a characteristic wavelength of 910 nm according to an example embodiment;

FIG. 5 illustrates a schematic top view of a ground-signal-ground VCSEL layout according to an example embodiment;

FIG. 6 illustrates a schematic top view of a ground-signal-ground VCSEL layout array according to an example embodiment;

FIG. 7 provides a plot showing simulation results of the photoluminescence (PL) spectrum of six different embodiments having various chemical compositions, and the spectrum of the cavity itself;

FIG. 8 provides plots showing the PL peak wavelength distributions of four different embodiments having various chemical compositions;

FIG. 9 provides plots showing the Fabry-Perot (FP) dip wavelength distributions of four different embodiments having various chemical compositions; and

FIG. 10 provides a flowchart illustrating various processes, procedures, and/or operations for manufacturing a VCSEL according to an example embodiment.

### DETAILED DESCRIPTION OF THE INVENTION

The present invention now will be described more fully hereinafter with reference to the accompanying drawings, in which some, but not all embodiments of the inventions are shown. Indeed, these inventions may be embodied in many different forms and should not be construed as limited to the embodiments set forth herein; rather, these embodiments are provided so that this disclosure will satisfy applicable legal requirements. Like numbers refer to like elements throughout. As used herein, terms such as “top,” “about,” “around,” etc. are used for explanatory purposes in the examples provided below to describe the relative position of certain components or portions of components. As used herein, the term “approximately” refers to tolerances within manufacturing and/or engineering standards.

FIG. 1 illustrates a typical ground-signal-ground vertical-cavity surface-emitting laser (VCSEL) layout 100 on an optical chip. As described herein, a VCSEL layout 100 comprises the position of a VCSEL and the position of contact layers connected to a VCSEL on an optical chip or wafer. The optical chip may comprise one or more VCSELs 102 in the VCSEL layout 100 or an array of VCSELs 102 arranged over a plurality of VCSEL layouts 100. The VCSEL 102 may be configured to output light for use in a variety of applications, such as fiber optic data transmission in high-speed fiber optic communication systems.

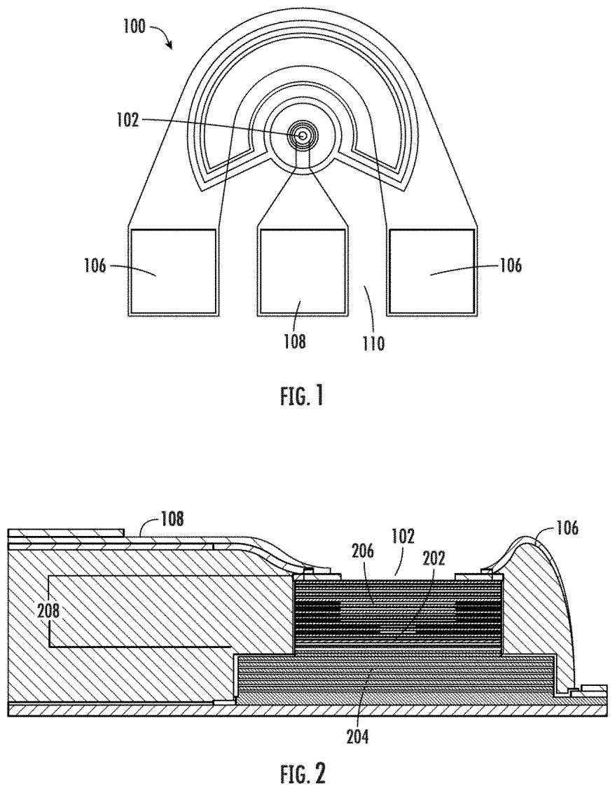

As shown in FIG. 2 the structure of the VCSEL 102 may include an active region 202 disposed between two reflector stacks 204 and 206. The active region may be configured to cause the VCSEL 102 to emit light having a characteristic wavelength of 910 nm. The VCSEL 102 may also include a mesa structure 208. Contact layers 108 and 106 may be provided on either side of the VCSEL 102 and may be configured to conduct electricity through the VCSEL 102, such that light having a characteristic wavelength of 910 nm can be generated in the active region 202 and the reflector stacks 204 and 206 (e.g., within a cavity defined thereby) and output through the top of the VCSEL 102, as shown in FIGS. 1 and 2. In some examples, the structure comprises metallic material to allow for future wire bonding.

Referring back to FIG. 1, the contact layer 106 may serve as an electrical ground, while the contact layer 108 may serve as the electrical signal layer that is configured to provide current to the VCSEL 102. For example, providing an electrical current to the contact layer 108 may energize the VCSEL 102 such that light (e.g., an optical signal) is output from the VCSEL 102 while the electrical circuit is completed by the contact layer 106. In various embodiments, the overall temperature of the VCSEL 102 may increase as a result of an electrical current being provided through the contact layer 106 to the VCSEL 102. For example, the VCSEL 102 may be in a “cold state” when electrical current is not being provided and the VCSEL is not outputting light, and the VCSEL 102 may begin to warm up as electrical current is provided by the contact layer 106. For example, the characteristic wavelength of the VCSEL 102 may be 910 nm, meaning that the VCSEL 102 is configured to emit light having a characteristic wavelength of 910 nm when the VCSEL 102 is in an active and/or warmed up state. In an example embodiment, the VCSEL 102 is in an active and/or warmed up state when the VCSEL 102 and/or components thereof are above 23° C.

In the manufacturing process, a photolithography process may be used to define bond pads including a gap 110 between the contact layer 108 and the contact layer 106. The process may then include depositing the contact pads on the bond pads and utilizing a lift off phase to remove excess conducting material.

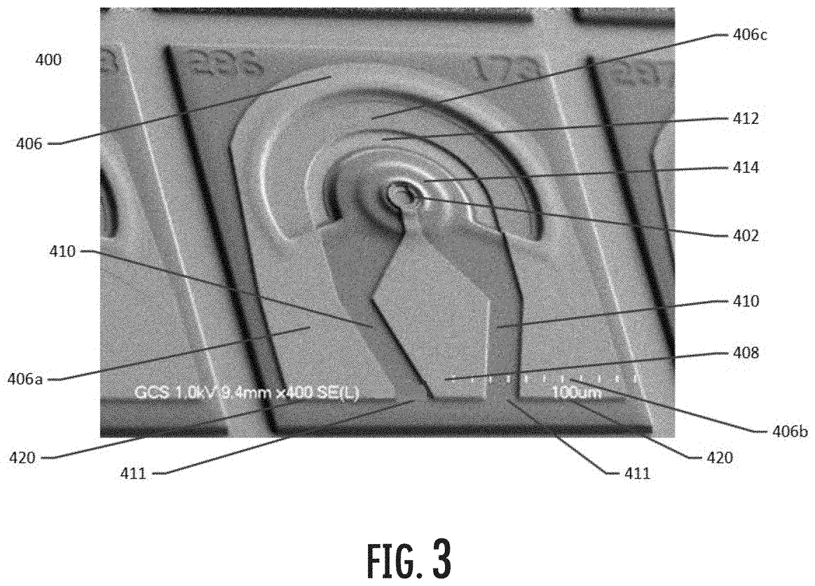

Through hard work and applied ingenuity, the inventors have discovered a new design of a VCSEL having a characteristic wavelength of 910 nm having sufficient gain for use in fiber optic communication applications. In some examples, the VCSEL layout 400 shown in FIG. 3 and described below reduces the parasitic properties of the VCSEL layout, such that the VCSEL may provide a high frequency optical signal (e.g., 30 GHz, 50 GHz, 70 GHz, and/or the like).

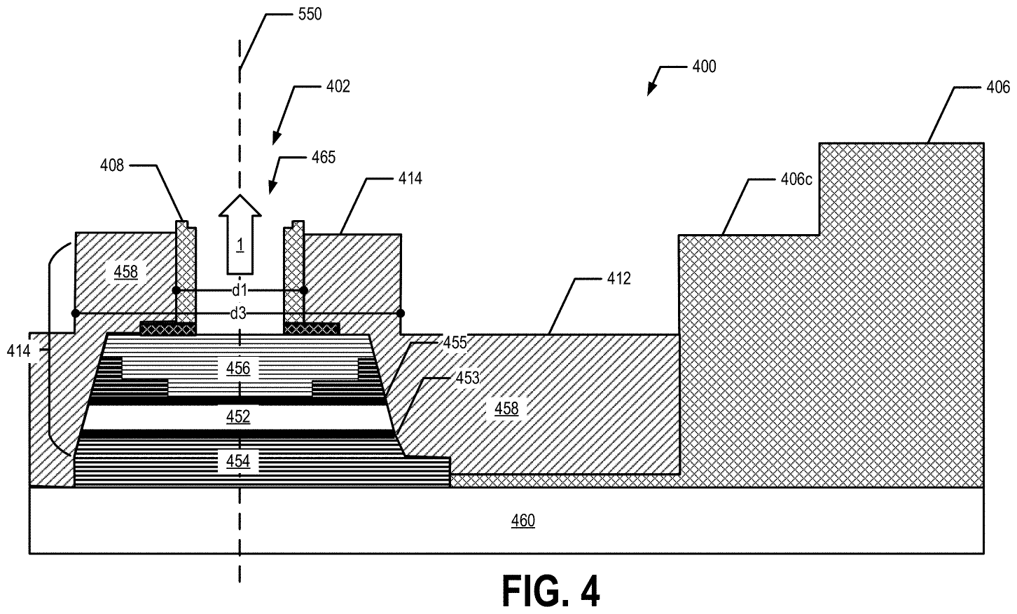

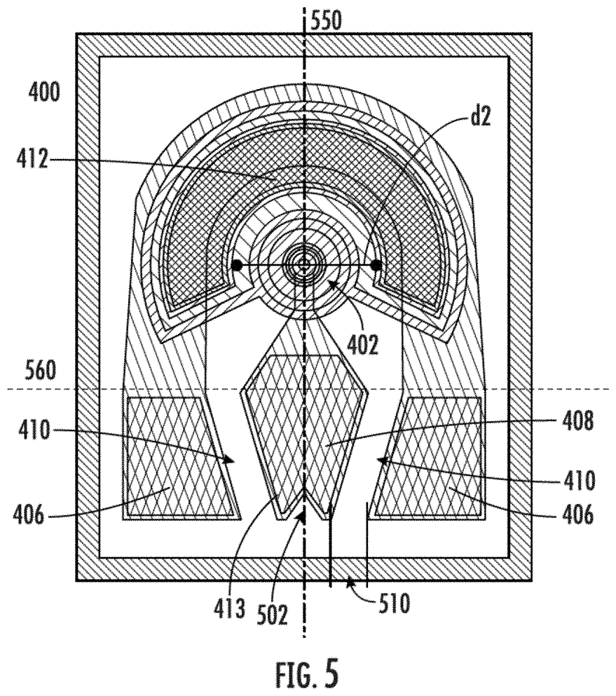

FIGS. 3-6 illustrate a ground-signal-ground VCSEL layout of a VCSEL having a characteristic wavelength of 910 nanometers, according to example embodiments. Specifically, FIG. 3 illustrates a top perspective view of a VCSEL layout 400 and FIG. 4 provides a cross-section of an example embodiment of the VCSEL layout 400 illustrated in FIG. 3. The VCSEL layout 400 includes a VCSEL 402, a first contact layer 408, a second contact layer 406, and a gap 410 between the first and second contact layers 406 and 408. In an example embodiment, the first contact layer 408 is a signal contact layer and the second contact layer 406 is a ground contact layer. In some examples, the material making up the contact layers may comprise gold. In some examples, the VCSEL 402 is similar to the VCSEL 102 described in FIG. 2. For example, an example embodiment of the VCSEL 402 may include an active region 452 disposed between two reflector stacks 454 and 456, and the active region 452 may be configured to cause the VCSEL 102 to emit light having a characteristic wavelength of 910 nm. The active region 452 and the reflector stacks 454 and 456 may define the mesa structure 414. For example, the mesa structure 414 may comprise the active region 452 sandwiched between the reflector stacks 454 and 456. The first contact layer 408 may encircle the VCSEL opening and/or emission window 465 such that the first contact layer 408 defines an aperture of the VCSEL 402 having a first diameter d1 and through which the light 1 is emitted from the VCSEL. For example, the first contact layer 408 may at least partially extend around the top of the mesa structure 414. In an example embodiment, the first diameter d1 is approximately 22.398 micrometers (μm). For example, the first diameter d1 may be 21-24 μm.

The second contact layer 406 may extend in an arc around the VCSEL 402 at a second diameter d2 that is greater than the first diameter d1. In an example embodiment, the second diameter d2 is approximately two to four times greater than the first diameter d1. In the illustrated embodiment of FIG. 3, the first contact layer 408 serves as the electrical signal layer that is configured to provide current to the VCSEL 402, and the second contact layer 406 serves as the electrical ground to complete the electrical circuit. The layout 400 may also include an etched section including an etched shape 412 about the mesa structure 414 of the VCSEL 402. In an example embodiment, the etched shape 412 may be a portion about the mesa structure 414 that has been etched down to a dielectric and/or insulating material 458. In an example embodiment, the insulating material 458 is Benzocyclobutene (BCB). In an example embodiment, the VCSEL 402 is formed on a substrate 460. For example, an arc-shaped trench may be etched about the mesa structure 414 between the first contact layer 408 and the second contact layer 406. In some examples, this process includes standard metallization in the P-N contact layer. For example, Ti/Pt/Au may be used for the P contact layer and Ge/Ni/Pt/Ti/Au may be used for the N contact layer.

In some examples, a VCSEL 402 characterized by the VCSEL layout 400 comprises the etched shape 412 around the mesa structure 414 of the VCSEL 402. The layout 400 may also include the first contact layer 408 deposited on a section of the mesa structure 414 of the VCSEL 402. The layout may also include the second contact layer 406. In various embodiments, the second contact layer 406 comprises three parts or portions. A first part 406c of the second contact layer 406 may be deposited on a section of the etched shape, and a second part 406a and a third part 406b of the second contact layer 406 may each comprise a leg extending from the first part. For example, the second contact layer 406 may comprise an arc portion, such as the first part 406c, and leg or extended portions, such as the second and third parts 406a and 406b. In an example embodiment, the first part 406c is an arc portion defined by the second diameter d2. In an example embodiment, the legs (second and third parts 406a and 406b) extend from opposite ends of the arc portion (the first part 406c) away from the arc portion such that a first end of each leg is at least partially in contact (e.g., in electrical contact) with the arc portion (the first part 406c) and a second end of each leg is disposed at a distal position with respect to the arc portion. The two legs or extended portions (the second and third parts 406a and 406b) may be symmetrically positioned about two sides of the first contact layer 408 to form a ground-signal-ground configuration. In an example embodiment, the first and second contact layers 408, 406 may be generally M-shaped. For example, the second and third parts 406a and 406b of the second contact layer 406 may provide the outer legs of the M shape, the first contact layer 408 may provide the middle leg of the M shape, and the first part 406c of the second contact layer 406 may provide an intermediate arched or bent portion connecting the two outer legs of the M shape.

In particular, the second part 406a and the third part 406b of the second contact layer 406 may be configured such that a distal end 420 of each (e.g., an end that is distal to the first part 406c) is wider than portions of the second and third parts 406a, 406b that are more proximal to the first part 406c. In this way, distal ends 411 of the gap 410 extend towards each other at the distal end 420 of the second and third parts 406a, 406b of the second contact layer 406. For example, the distal end 413 of the first contact layer 408 is the end of the first contact layer 408 that is distal to the mesa structure 414. The distal end 413 of the first contact layer 408 may be tapered. For example, the second and third parts 406a and 406b (e.g., the legs and/or extended portions of the second contact layer 406) may widen starting at an inflection point 560 and continue to widen toward the distal ends 420 thereof and the first contact layer 408 may narrow or taper starting at the inflection point 560 and continue to narrow toward the distal end 413 of the first contact layer. In an example embodiment, the second and third parts 406a and 406b (e.g., the legs and/or extended portions of the second contact layer 406) may taper or narrow between the first part 406c and the inflection point. For example, the width of the second and third parts 406a and 406b (e.g., the legs and/or extended portions of the second contact layer 406) may be smaller at the inflection point 560 compared to where the second and third parts 406a and 406b extend from and/or contact the first part 406c of the second contact layer 406. In an example embodiment, the width of the second and third part 406a and 406b may be approximately constant between the first part 406c and the inflection point 560. In an example embodiment, the inflection point 560 is located closer to the mesa structure 414 of the VCSEL layout 402 than to the distal ends 420, 413 of the first and second contact layers 408, 406. In an example embodiment, the first part 406c may comprise an arc portion and the second and third parts 406a, 406b, may comprise a first leg portion and a second leg portion that extend symmetrically from opposite ends of the arc portion.

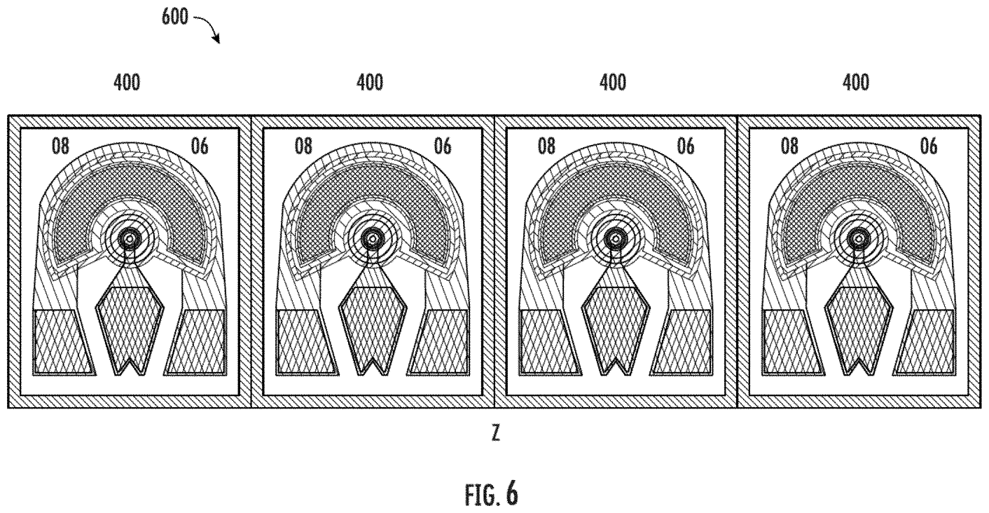

The inventors have determined that the layout shown in FIG. 3 provides more current to the VCSEL 402 than standard layouts and reduces the amount of current that would be parasitically drained through other materials in the VCSEL layout 400. In particular, the “M”-like shape provided by the second contact layer 406 and the first contact layer 408 extending therebetween (e.g., between a second part 406a and a third part 406b) reduces the parasitics of the VCSEL 402. The increased current sent directly to the VCSEL 402 provides the increased frequency of the optical signal output from the VCSEL 402. In some examples, the VCSEL 402 also provides low cross talk between neighboring VCSELs such as shown in the VCSEL array 600 depicted in FIG. 6. The VCSEL 402 may also provide low noise levels and facilitate testing through the use of a notch 502 through pattern recognition for standard testing of the VCSEL.

As shown in FIGS. 3-6, the VCSEL layout 400 includes the etched shape 412. As described above, the etched shape 412 further decreases the parasitic materials around the mesa of VCSEL 402, to lower the parasitic capacitance of the VCSEL layout 400. In some examples, the etched shape 412 comprises an arc and/or a half or semi-circle shape, such as a “C” shape around the mesa of the VCSEL 402. For example, the etched shape 412 may be a portion of an annulus defined by the first diameter d1 or by the mesa diameter d3 at the interior edge of the annulus and the second diameter d2 at the outer edge of the annulus.

As shown in FIG. 4, the first part 406c of the second contact layer 406 and the etched shape 412 may comprise a stepped feature such that the thickness of the VCSEL is smaller proximate the mesa structure 414 than at other positions of the VCSEL layout 402. For example, the distance between the substrate 460 and the exterior surface of the VCSEL may be smaller at the etched shape 412 than at other portions of the VCSEL (e.g., in the gap 410, the first part 406c of the second contact layer 406, the second or third parts 406a, 406b of the second contact layer 406, and/or the first contact layer 408). In an example embodiment, the etched shape 412 extends around at least half of the perimeter of the mesa 414 (e.g., at least halfway around the circumference defined by d3). In an example embodiment, the etched shape 412 extends around greater than half the perimeter of the mesa structure 414 (e.g., approximately 60% of the way around, 66.67% of the way around, 75% of the way around, and/or the like).

Furthermore, in some examples, the VCSEL layout 400 is symmetrical such that the gap 410 on both sides of the first contact layer 408 and between the first contact layer 408 and the second contact layer 406 are the same shape and distance on both sides of an axis 550. For example, the width of the gap 410 between the first contact layer 408 and the legs of the second contact layer 406 may be the same on both sides of the first contact layer 408. The gap 410 may, for example, have a width 510. In some examples, the width 510 is approximately 19.23213 μm. In other examples, the width 510 may be between 19 μm and 20 μm. In any of the above examples, the gap 410 may be the same on both sides of the first contact layer 408. For example, a gap 410 may be disposed between the second part 406a (e.g., a first leg) of the second contact layer 406 and the first contact layer 408 such that the gap 410 separates the second part 406a (e.g., a first leg) of the second contact layer 406 from the first contact layer 408 by a first width. Similarly, a gap 410 may be disposed between the third part 406b (e.g., a second leg) of the second contact layer 406 and the first contact layer 408 such that the gap 410 separates the third part 406b (e.g., a second leg) of the second contact layer 406 from the first contact layer 408 by a second width. The first and second widths may be approximately equal.

In another example embodiment, the VCSEL layout 400 includes a notch 502 in the first contact layer 408. The notch 502 may be a probe notch configured to provide a guide for a testing probe in the testing stage of VCSEL manufacturing. The notch 502 may thus allow the probe to more easily make contact with the first contact layer 408, such that the probe can provide a testing electrical current to the VCSEL 402. In an example embodiment, the notch 502 is a V-shaped notch; however, various other notch shapes are considered. In an example embodiment, the notch 502 has an opening that is 20 to 25 μm wide and that is disposed on an edge or surface of the first contact layer 408. In an example embodiment, the notch extends 10 to 25 μm into the first contact layer 408.

In various embodiments, the mesa structure 414 comprises first and second reflector stacks 454, 456. In various embodiments, the first and second reflector stacks 454, 456 may each comprise multiple reflector layers. For example, the first reflector stack 454 may be and/or may comprise a number of distributed Bragg reflector (DBR) mirrors, each mirror being a reflector layer. In another example, the first reflector stack 454 may comprise an un-doped semiconductor distributed Bragg reflector (DBR) mirror and/or dielectric reflector stacks. Similarly, the second reflector stack 456 may comprise a number of DBR mirrors and/or reflector layers. In various embodiments, the first and second reflector stacks 454, 456 sandwich the active region 452. In an example embodiment, a first surface of the first reflector stack 454 is adjacent, affixed to, abuts, and/or is similarly positioned with respect to the second surface of the substrate 460. In an example embodiment, a second surface of the first reflector stack 454 is opposite the first surface of the first reflector stack in a direction defined by and/or parallel to the light emission axis 550. In various embodiments, at least a portion of a second surface of the first reflector stack 454 is adjacent, affixed to, abuts, and/or is similarly positioned with respect to a first current-spreading layer 453. In various example embodiments, the second surface of the first reflector stack 454 and/or the reflector layer of the first reflector stack closest to the active region 452 may be and/or may comprise a buffer layer. This buffer layer may have a thickness greater than that of the other reflector layers of the first reflector stack 454, thereby causing the VCSEL to emit light having a characteristic wavelength of 910 nm. For example, the thickness of the buffer layer may be a configurable parameter to control a characteristic wavelength of light emitted by the VCSEL. For example, the thickness of the buffer layer may aid in defining a VCSEL cavity having a resonant wavelength such that the VCSEL emits light having a characteristic wavelength of 910 nm. The thickness of the other reflector layers of the first reflector stack 454 may also contribute to the VCSEL emitting light having a characteristic wavelength of 910 nm.

In various embodiments, a first surface of the second reflector stack 456 is adjacent, affixed to, abuts, and/or is similarly positioned with respect to the second current-spreading layer 455. In an example embodiment, a second surface of the second reflector stack 456 is opposite the first surface of the second reflector stack 456 in a direction defined by and/or parallel to the light emission axis 550. In various embodiments, at least a portion of a second surface of the second reflector stack 456 is adjacent, affixed to, abuts, and/or is similarly positioned with respect to a layer of dielectric and/or insulating material 458 and/or first contact layer 408. In various example embodiments, the first surface of the second reflector stack 456 and/or the reflector layer of the first reflector stack closest to the active region 452 may be and/or may comprise a buffer layer. This buffer layer may have a thickness greater than that of the other reflector layers of the second reflector stack 456, thereby causing the VCSEL to emit light having a characteristic wavelength of 910 nm. In example embodiments, the buffer layer of the second reflector stack 456 and the buffer layer of the first reflector stack 454 are the same thickness. In example embodiments, the ratio of thickness between the buffer layer of the second reflector stack 456 and the other reflector layers of the second reflector stack 456 is the same as the ratio of thickness between the buffer layer of the first reflector stack 454 and the other reflectors layers of the first reflector stack 454.

In an example embodiment, the first and second reflector stacks 454, 456 comprise an un-doped semiconductor distributed Bragg reflector (DBR) mirror and/or dielectric reflector stacks. For example, the first reflector stack 454 may comprise un-doped alternating layers of aluminum gallium arsenide (AlGaAs) and gallium arsenide (GaAs). In an example embodiment, the first reflector stack 454 has approximately 98% reflectivity from the perspective of active region 452 In an example embodiment, the first and/or second reflector stacks 454, 456 comprise 10-25 pairs of layers of GaAs/AlGaAs. For example, in an example embodiment, the first reflector stack 454 may comprise 25 layers of GaAs and 25 layers of AlGaAs wherein the layers are disposed such that the layers alternate between a GaAs layer and an AlGaAs layer. For example, a pair of layers may consist of a GaAs layer and an abutting AlGaAs layer. In an example embodiment, the thickness of each layer is approximately one-fourth λ/n, where λ is emission wavelength and n is the refractive index of a semiconductor of that layer. For example, the thickness of each layer of the first and second reflector stacks 454, 456 may be epitaxially grown to a thickness corresponding to the desired wavelength tuning of the VCSEL cavity of the VCSEL 402, specifically 910 nm.

In various embodiments, the first and second contact layers 406, 408 are each in electrical communication with one of the first and second current-spreading layers 453, 455. For example, in an example embodiment, the first contact layer 406 is in electrical communication with the first current-spreading layer 453 and the second contact layer 408 is in electrical communication with the second current-spreading layer 455. In another example embodiment, the first contact layer 406 is in electrical communication with the second current-spreading layer 455 and the second contact layer 408 is in electrical communication with the first current-spreading layer 453.

In various embodiments, the active region 452 is sandwiched and/or disposed between the first and second current-spreading layers 453, 455 and is configured to cause the VCSEL to emit light having a characteristic wavelength of 910 nm. In various embodiments, the active region 452 is in electrical communication with the first and second current-spreading layers 453, 455. In various embodiments, the active region 452 comprises a plurality of quantum wells, where radiation 1 is generated, between the first and second reflector stacks 454, 456. In some various embodiments, the active region 452 may comprise a multi-quantum well (MQW) layer stack comprising a series of quantum wells disposed between a series of barriers, and a p-type region (layer) disposed between the second current-spreading layer 455 and the MQW layer stack. For example, a second surface of the active region 452 (e.g., the surface proximate the second current-spreading layer 455) may comprise a p-type layer. In an example embodiment, the series of quantum wells and barriers may comprise six un-doped compressively-strained indium aluminum gallium arsenide (InAlGaAs) quantum wells and seven tensile-strained InAlGaAs barriers.

In various embodiments, the InGaAs wells may have a high level of Indium (up to 18%). For example, the wells may be characterized by InₓGa₍₁₋ₓ₎As, where x is in the range of 0.1 to 0.2, 0.11 to 0.14, 0.14 to 0.18, or 0.11 to 0.18, in various embodiments. In various embodiments, the thickness of each InAlGaAs layer is in the range of 3.5 nm to 6 nm. In various embodiments, the thickness of each InAlGaAs layer is in the range of approximately 4.0 nm to 5.6 nm.

In various embodiments, the AlGaAs barriers may have low levels of Aluminum. For example, the barriers may be characterized by Al_{y}Ga_{(1-y)}As, where y is in the range of 0.05 to 0.35, 0.05 to 0.25, or 0.05 to 0.2, in various embodiments. In various embodiments, the thickness of each AlGaAs barrier layer is approximately 6 nm. In various example embodiments, the thickness of each AlGaAs barrier layer as well as the aluminum content of each AlGaAs barrier layer are configured to cause the VCSEL to emit light having a characteristic wavelength of 910 nm. For example, the thickness of the AlGaAs barrier layers may be directly (or indirectly) proportional to a characteristic wavelength of light emitted by the VCSEL. Similarly, the aluminum content may also be directly (or indirectly) proportional to a characteristic wavelength of light emitted by the VCSEL.

FIG. 6 illustrates a VCSEL array 600 on an optical chip, including one or more VCSELs characterized by the VCSEL layout 400. Specifically, FIG. 6 illustrates an example embodiment of an optical chip with four VCSELs adjacent to each other horizontally. In an example embodiment, an optical chip may have a different number of VCSELs positioned in different dimensions. For example, an optical chip may feature a 5×3 VCSEL grid. In another example embodiment, an optical chip may only allow a number of VCSELs to be positioned in one dimension to allow electronic connections to attach to the contact layers of each VCSEL. In various example embodiments, each VCSEL of the VCSEL array 600 on an optical chip may emit light with a characteristic wavelength of 910 nm. In an example embodiment, each VCSEL of the VCSEL array 600 may be a tunable VCSEL having a characteristic wavelength of 910 nm. In other example embodiments, each VCSEL of the VCSEL array 600 may emit light with different and/or unique characteristic wavelengths. For example, one VCSEL of the VCSEL array 600 may emit light with a characteristic wavelength of 910 nm, another with a characteristic wavelength of 850 nm, another with a characteristic wavelength of 1100 nm, another with a characteristic wavelength of 1310 nm, and so forth.

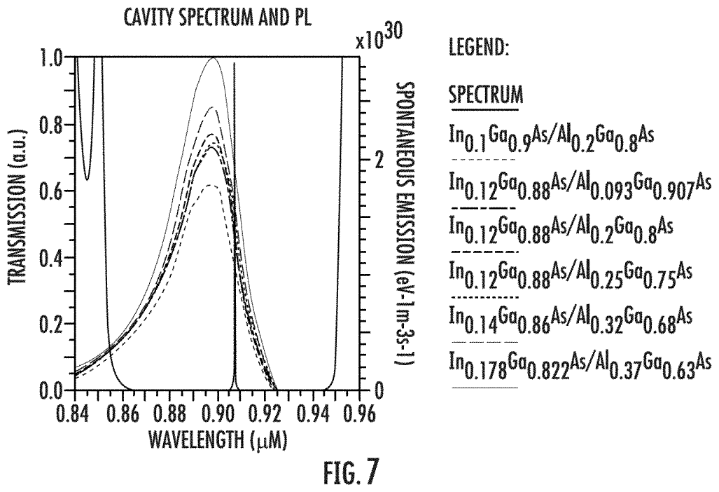

FIG. 7 provides a plot showing simulation results of the photoluminescence (PL) spectrum of six different embodiments having various values of x and/or y (x and y referring to the above mentioned indium and aluminum contents, respectively, of the quantum well layers and barrier layers) and the spectrum of the VCSEL cavity itself (e.g., as tuned at least via the thickness of the layers of the first and second reflector stacks 454, 456). FIG. 7 illustrates the spectrums of a cold cavity and a non-operating laser (e.g., a device with a low temperature (e.g., approximately 23° C. or less) and without current).

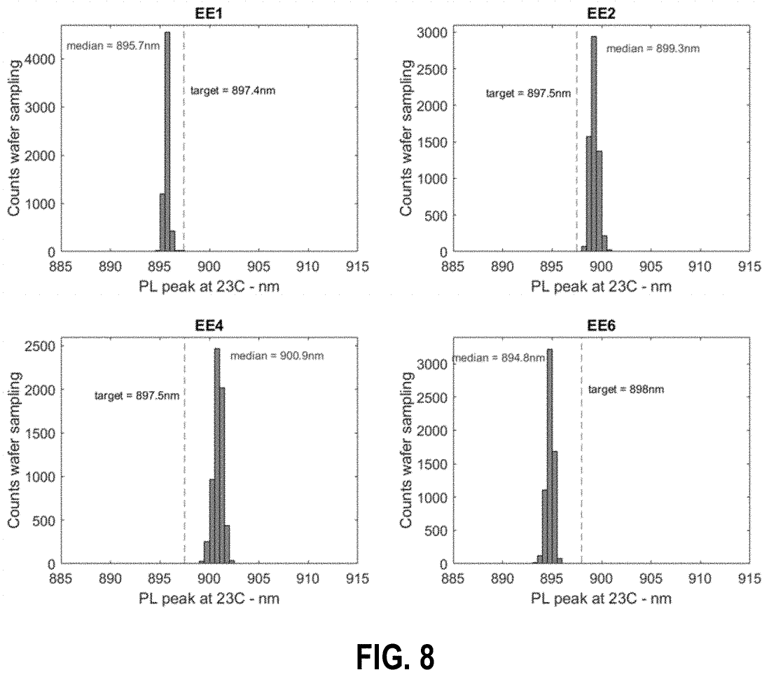

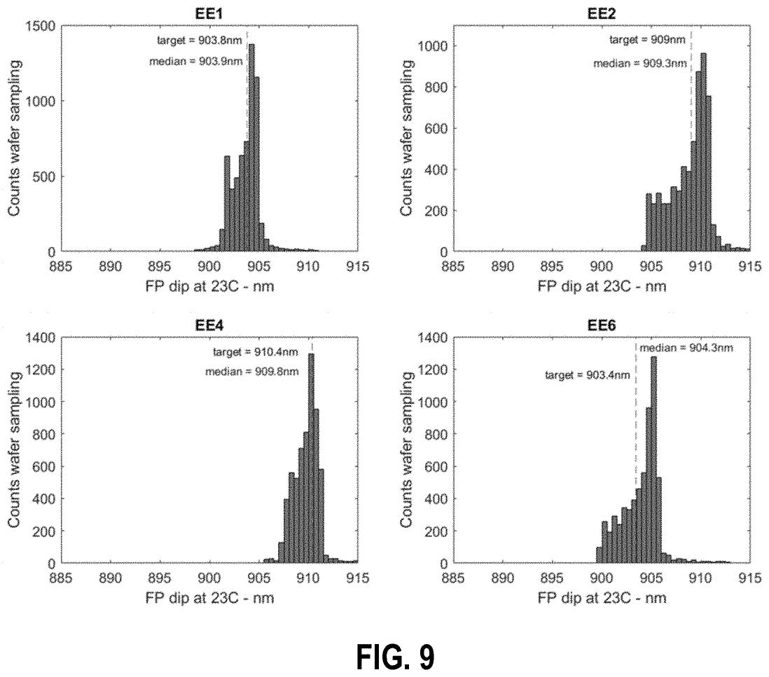

The results Table 1 describes various parameters of each of the six illustrated example embodiments (EEs), corresponding to the six embodiments illustrated in FIG. 7, some of which are also illustrated in FIGS. 8 and 9.

TABLE 1

| EE1: | EE2: | EE3: | EE4: | EE5: | EE6: |
|---|---|---|---|---|---|
| x = 0.1 | x = 0.12 | x = 0.12 | x = 0.14 | x = 0.178 | x = 0.12 |
| y = 0.2 | y = 0.2 | y = 0.25 | y = 0.32 | y = 0.37 | y = 0.093 |
| Well | Well | Well | Well | Well | Well |
| layer | layer | layer | layer | layer | layer |
| thickness: | thickness: | thickness: | thickness: | thickness: | thickness: |
| 5.6 nm | 4.8 nm | 5.1 nm | 4.7 nm | 4 nm | 4 nm |
| Barrier | Barrier | Barrier | Barrier | Barrier | Barrier |
| layer | layer | layer | layer | layer | layer |
| thickness: | thickness: | thickness: | thickness: | thickness: | thickness: |
| 6 nm | 6 nm | 6 nm | 6 nm | 6 nm | 6 nm |

As can be seen in FIG. 7 the cavity spectrum and the active region may each be tuned to a wavelength slightly below the characteristic wavelength of the VCSEL. For example, FIG. 7 shows the cavity spectrum tuned to peak at a wavelength of approximately 907 nm and the PL spectrum of the active region 452 (e.g., the MQW layer stack) designed to have a PL peak of approximately 898 nm. In various embodiments, the cavity may be tuned to have a spectral peak of approximately 900 to 910 nm. In various embodiments, the active region may be designed to have a PL peak of approximately 895 to 905 nm. These spectral peaks correspond to the situation where the cavity is cold and the laser is not operating (e.g., a device with a low temperature (e.g., approximately 23° C. or less) and without current). The difference between the cavity peak and the PL peak accounts for the difference in temperature coefficients of various elements of the VCSEL 402, such that once the VCSEL 402 is warmed up and operating in an active and/or warmed state (e.g., greater than 23° C.), the spectral peaks of the cavity and the active region will approximately align. In various embodiments, this approximate alignment happens at a wavelength of approximately 910 nm. For example, the active region 452 (e.g., the MQW layer stack) may have a different temperature coefficient than the first and second reflector stacks 454, 456.

FIG. 8 provides plots showing the distribution of photoluminescence (PL) peaks for four different embodiments. Specifically, the distribution of PL peaks for embodiments EE1, EE2, EE4, and EE6 at 23° C. are shown. As seen above in Table 1, each embodiment varies in some tuned parameters, specifically the indium content in the quantum well layers of the active region, the aluminum content in the barrier layers of the active region, and the thickness of the well layers. As stated above with respect to FIG. 7 and shown again in FIG. 8, the PL spectrum of the active region 452 may be designed to have a PL peak of approximately 898 nm, shown by the dashed line in each histogram plot. FIG. 8 further illustrates that the PL peak wavelength may vary in distribution by about 2 nm depending at least upon the tuned parameters of the indium and aluminum contents of the quantum well and barrier layers, respectively, and the quantum well layer thicknesses. FIG. 8 also shows that in various embodiments, there may be a small offset of about 3.5 nm between the designed PL peak target (shown by the dashed line) and a measured PL peak of the VCSEL. For example, EE1 and EE6 have a measured PL peak detuned to a shorter wavelength than their respective PL peak target, while EE2 and EE4 have a measured PL peak detuned to a higher wavelength than their respective PL peak targets. Overall, FIG. 8 shows that in various example embodiments, different active regions may be tuned to a specific PL peak target.

FIG. 9 provides plots showing the distribution of Fabry-Perot (FP) dip wavelengths of four different embodiments. Specifically, the distribution of FP dip wavelengths for embodiments EE1, EE2, EE4, and EE6 at 23° C. are shown (again see Table 1 for parameter values such as indium and aluminum content levels and quantum well layer thicknesses). In various example embodiments, a cavity dip wavelength may be intentionally detuned with respect to the designed PL peak target (described in context of FIG. 8). For example, FIG. 9 illustrates a designed PL peak and cavity dip detuning of approximately 8.1, 9.7, 9.5, and 8.6 nm for EE1, EE2, EE4, and EE6, respectively. Similar to the target PL peaks in FIG. 8, the target FP dip wavelengths are shown by dashed lines in each plot of FIG. 9. FIG. 9 further illustrates that the FP dip wavelengths may vary in distribution by about 5 nm, thus spanning a range of 900 to 910 nm that includes the target FP dip wavelength. In various embodiments, the cavity FP dip wavelengths may be adjusted by adjusting parameters associated with the reflector layers of the reflector stacks, such as thickness.

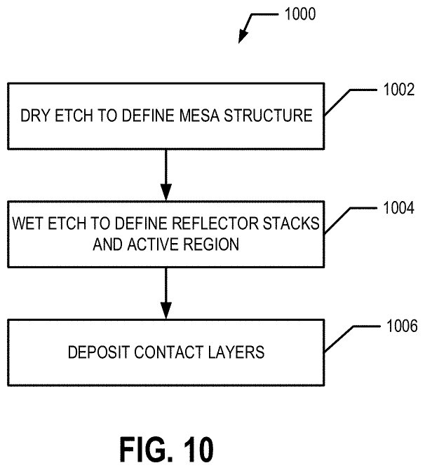

FIG. 10 provides a flowchart illustrating an example process 1000 for manufacturing a VCSEL 402 according to embodiments described herein. Starting at block 1002, a VCSEL blank may be dry-etched to define one or more mesa structures. For example, the VCSEL blank may be formed on a substrate which may comprise a first layer from which a first reflector stack may be formed, a second layer from which an active region may be formed, a third layer from which a second reflector stack may be formed, a fourth layer from which a first contact layer may be formed, a fifth layer from which a second contact layer may be formed, and/or the like. In an example embodiment, the VCSEL blank comprises a sixth layer from which a cap layer may be formed. In an example embodiment, the first and third layers may comprise a plurality of un-doped alternating layers of AlGaAs and GaAs for forming DBR mirrors of the first and second reflector stacks 454, 456. For example, the first and third layers, possibly in combination with the second layer, are configured, when etched to define at least a portion of a mesa, define a VCSEL cavity configured to have a resonant wavelength that enables a VCSEL 402 characterized by VCSEL layout 400 to have a characteristic wavelength of 910 nm. In an example embodiment, the second layer comprises a material from which the active region 452 may be formed and configured to cause the VCSEL to emit light having a characteristic wavelength of 910 nm. For example, the second layer may comprise a multi-quantum well (MQW) layer stack comprising a series of quantum wells disposed between a series of barriers. In an example embodiment, the second layer comprises a p-type region (layer) disposed between the MQW layer stack and the third layer of the VCSEL blank.

The VCSEL blank may be dry etched to form and/or define one or more mesas (e.g., mesa structure 414). In an example embodiment, the VCSEL blank is dry etched in Ar-SiC14 plasma. In an example embodiment, the VCSEL blank is dry etched using a photoresist or dielectric mask.

Continuing with FIG. 10, at block 1004 wet etching may be used to define and/or form the active region 452 and the first and second reflector stacks 454, 456. For example, in an example embodiment, the wet etching is done by selective chemical etching in H₃PO₄—H₂O₂—H₂O solutions. For example, the mesa structure 414 may be wet etched to define and/or to finish defining the emission structure. For example, the first reflector stack 454 may have a diameter that is larger than the remainder of the mesa structure 414.

At block 1006, the first and second contact layers 408, 406 may be deposited and/or formed on the cap layer 170. For example, various metal deposition techniques may be used to deposit the contact layers 406, 408 on the mesa structure 414 and/or the VCSEL 402. In an example embodiment, the first contact layer 408 is deposited around the emission window 465 in a circular shape with a first diameter d1. In an example embodiment, the second contact layer 406 is deposited and/or formed such that the second contact layer 406 forms an arc shape with a second diameter d2 greater than the first diameter d1. For example, the second diameter d2 may be two to four times greater than the first diameter d1.

As should be understood by one skilled in the art in light of this disclosure, once a VCSEL 402 (e.g., a VCSEL characterized by VCSEL layout 400) has been formed, manufactured, and/or the like, the VCSEL may be secured, affixed, or otherwise mounted to a circuit board. For example, a VCSEL 402 may be secured, affixed, and/or mounted to a circuit board such that the first contact layer is mechanically secured to a first lead such that the first contact is in electrical communication with the first lead. For example, a VCSEL 402 may be secured, affixed, and/or mounted to a circuit board such that the second contact layer is mechanically secured to a second lead such that the second contact layer is in electrical communication with the second lead, which may be an electrical ground. Mounting a VCSEL 402 to a circuit board may therefore manufacture, generate, form, and/or otherwise result in a board-mounted VCSEL.

Many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific embodiments disclosed and that modifications and other embodiments are intended to be included within the scope of the appended claims. Although specific terms are employed herein, they are used in a generic and descriptive sense only and not for purposes of limitation.

1. A vertical-cavity surface-emitting laser (VCSEL) comprising:
a mesa structure disposed on a substrate, the mesa structure comprising:
a first reflector stack,
a second reflector stack, and
an active region disposed between the first and second reflector stacks, wherein the active region is configured to cause the VCSEL to emit light having a characteristic wavelength of 910 nanometers;
a first contact layer configured to serve as an electrical signal layer and disposed at least in part on a surface of the mesa structure opposite the substrate; and
a second contact layer configured to serve as an electrical ground and disposed at least partially around the mesa structure.

2. The VCSEL of claim 1, wherein the active region is comprised of a plurality of quantum wells each comprising up to 18% indium and a plurality of barriers each comprising 5 to 37% aluminum.

3. The VCSEL of claim 1, wherein the active region is comprised of a plurality of alternating layers of quantum wells and barriers, each quantum well layer comprising an indium gallium arsenide alloy and each barrier layer comprising an aluminum gallium arsenide alloy.

4. The VCSEL of claim 3, wherein the thickness and aluminum content of each barrier layer is configured to cause the VCSEL to emit light having a characteristic wavelength of 910 nanometers.

5. The VCSEL of claim 4, wherein each of the first and second reflector stacks is comprised of a plurality of reflector layers, and wherein the thickness of each reflector layer is configured to cause the VCSEL to emit light having a characteristic wavelength of 910 nanometers.

6. The VCSEL of claim 5, wherein each of the first and second reflector stacks is further comprised of a buffer layer bordering the active region, each buffer layer having a thickness greater than the thickness of remaining reflector layers of the plurality of reflector layers.

7. The VCSEL of claim 1, wherein the first contact layer extends in at least a partial circular shape around an emission window of the VCSEL and has a first diameter and the second contact layer extends in an arc around the mesa structure and has a second diameter greater than the first diameter.

8. The VCSEL of claim 7, wherein the second diameter is two to four times greater than the first diameter.

9. The VCSEL of claim 1, wherein a cavity resonance of a VCSEL cavity formed by the first and second reflector stacks and a photoluminescence peak of the active region are detuned to below the characteristic wavelength of 910 nanometers in an instance in which the first contact layer is not conducting an electrical current and the VCSEL has a temperature below 23 degrees Celsius.

10. The VCSEL of claim 9, wherein the cavity resonance and the photoluminescence peak of the active region are configured to shift towards 910 nanometers in an instance in which the first contact layer conducts electrical current and the VCSEL increases in temperature above 23 degrees Celsius.

11. A method for manufacturing a vertical-cavity surface-emitting laser (VCSEL), the method comprising:
dry etching a VCSEL blank to define a mesa structure disposed on a substrate;
wet etching the mesa structure to define:
a first reflector stack,
a second reflector stack, and
an active region disposed between the first and second reflector stacks, wherein the active region is configured to cause the VCSEL to emit light having a characteristic wavelength of 910 nanometers;
depositing a first contact layer at least in part on a surface of the mesa structure opposite the substrate, the first contact layer configured to serve as an electrical signal layer; and
depositing a second contact layer at least partially around the mesa structure, the second contact layer configured to serve as an electrical ground.

12. The method of claim 11, wherein the active region is comprised of a plurality of quantum wells each comprising up to 18% indium and a plurality of barriers each comprising 5 to 37% aluminum.

13. The method of claim 11, wherein the active region is comprised of a plurality of alternating layers of quantum wells and barriers, each quantum well layer comprising an indium gallium arsenide alloy and each barrier layer comprising an aluminum gallium arsenide alloy.

14. The method of claim 13, wherein the thickness and aluminum content of each barrier layer is configured to cause the VCSEL to emit light having a characteristic wavelength of 910 nanometers.

15. The method of claim 14, wherein each of the first and second reflector stacks is comprised of a plurality of reflector layers, and wherein the thickness of each reflector layer is configured to cause the VCSEL to emit light having a characteristic wavelength of 910 nanometers.

16. The method of claim 15, wherein each of the first and second reflector stacks is further comprised of a buffer layer bordering the active region, each buffer layer having a thickness greater than the thickness of remaining reflector layers of the plurality of reflector layers.

17. The method of claim 11, wherein the first contact layer extends in an at least partially circular shape around an emission window of the VCSEL and has a first diameter and the second contact layer extends in an arc around the mesa structure and has a second diameter greater than the first diameter.

18. The method of claim 17, wherein the second diameter is two to four times greater than the first diameter.

19. The method of claim 11, wherein a cavity resonance of a VCSEL cavity formed by the first and second reflector stacks and a photoluminescence peak of the active region are detuned to below the characteristic wavelength of 910 nanometers in an instance in which the first contact layer is not conducting an electrical current and the VCSEL has a temperature below 23 degrees Celsius.

20. The method of claim 19, wherein the cavity resonance and the photoluminescence peak of the active region are configured to shift towards 910 nanometers in an instance in which the first contact layer conducts electrical current and the VCSEL increases in temperature above 23 degrees Celsius.

21. The VCSEL of claim 1, wherein the characteristic wavelength of 910 nm corresponds to a wavelength range of 895 to 915 nm.

22. The method of claim 11, wherein the characteristic wavelength of 910 nm corresponds to a wavelength range of 895 to 915 nm.
